(19) United States
(12) Patent Application Publication
(10) Pub. No.: US 2016/0095203 A1
(43) Pub. Date: Mar. 31, 2016

(54) CIRCUIT BOARD

(71) Applicant: Samsung Electro-Mechanics Co., Ltd., Suwon-Si (KR)

(72) Inventors: Tae Hong MIN, Suwon-Si (KR); Myung Sam KANG, Hwaseong-si (KR); Young Gwan KO, Seoul (KR); Min Jae SEONG, Mungyeong-si (KR); Jin Hyuk JANG, Hanam-si (KR)

(73) Assignee: SAMSUNG ELECTRO-MECHANICS CO., LTD., Suwon-Si (KR)

(21) Appl. No.: 14/870,572

(22) Filed: Sep. 30, 2015

(30) Foreign Application Priority Data
Sep. 30, 2014 (KR) 10-2014-0130890

(51) Int. Cl. H05K 1/02; H05K 1/14; H05K 1/18; H05K 1/11

(52) U.S. Cl. CPC H05K 1/0207; H05K 1/0206; H05K 1/0209; H05K 1/0271; H05K 1/0298; H05K 1/115; H05K 1/111; H05K 1/142; H05K 1/181; H05K 1/183; H05K 2201/049

(57) ABSTRACT

Disclosed herein is a circuit board including a heat transfer structure formed of a highly thermal conductive material, wherein a part of the heat transfer structure excluding an air cooling unit exposed to outside of an insulation unit is inserted into an insulation unit, and the air cooling unit has a shape having a high non-surface area such as a wrinkled or uneven shape.

### CROSS REFERENCE(S) TO RELATED APPLICATIONS

This application claims the benefit under 35 U.S.C. Section[120, 119, 119(e)] of Korean Patent Application Serial No. 10-2014-0130890, entitled “Circuit Board” filed on Sep. 30, 2014, which is hereby incorporated by reference in its entirety into this application.

### BACKGROUND OF THE DISCLOSURE

1. Technical Field

The present disclosure relates to a circuit board.

2. Description of the Related Art

To meet the trend of lightweight, small-sized, high-speed, multifunctional, and high-functional electronic devices, multilayer substrate technologies of forming a plurality of wiring layers on a circuit board such as a printed circuit board (PCB) have been developed. Furthermore, a technology of mounting electronic parts such as an active device or a passive device on a multilayer substrate has been developed.

Meanwhile, as an application processor (AP) connected to the multilayer substrate has been multifunctional and high-functional, a heating amount is remarkably increasing.

### RELATED ART DOCUMENT

### Patent Document

(Patent Document 1) JP 2000-349435 A1

(Patent Document 2) JP 1999-284300 A1

### SUMMARY OF THE DISCLOSURE

An object of the present disclosure is to provide a circuit board capable of at least one of improving a heat dissipation performance of the circuit board, implementing a lightweight, thin, short, and small circuit board, improving reliability, reducing noise, and improving manufacturing efficiency.

The object of the present disclosure is not limited as described above, and other objects that are not mentioned will be understood by one of ordinary skill in the art from the description below.

According to an exemplary embodiment of the present disclosure, there is provided a circuit board including a first heat transfer structure formed of a highly thermal conductive material. In this regard, a part of the first heat transfer structure excluding an air cooling unit exposed to outside of an insulation unit may be inserted into an insulation unit. The air cooling unit may have a shape having a high non-surface area such as a wrinkled or uneven shape.

According to an exemplary embodiment of the present disclosure, the first heat transfer structure may be formed of a metal material such as copper. According to another exemplary embodiment of the present disclosure, the first heat transfer structure may be formed of a non-metal material having a high thermal conductivity such as graphite, graphene, etc.

Meanwhile, a primer layer may be provided on a surface of the first heat transfer structure.

### BRIEF DESCRIPTION OF THE DRAWINGS

FIG. 1 is a schematic cross-sectional view of a circuit board according to an embodiment;

FIG. 2 is a schematic cross-sectional view of a circuit board according to another embodiment;

FIG. 3 is a schematic cross-sectional view of a circuit board according to another embodiment;

FIG. 4 is a schematic plan view of a circuit board according to an embodiment;

FIG. 5 is a schematic horizontal cross-sectional view of a circuit board according to an embodiment;

FIG. 6 is a schematic horizontal cross-sectional view of a circuit board according to another embodiment;

FIG. 7 is a schematic partial cross-sectional view of a main part of a circuit board according to an embodiment;

FIG. 8 is a diagram for explaining a second heat transfer structure according to an embodiment;

FIG. 9 is a diagram for explaining a second heat transfer structure according to another embodiment;

FIG. 10 is a diagram for explaining a second heat transfer structure according to another embodiment;

FIG. 11A is a schematic diagram of a result of performing a reflow test in a state where a primer layer is provided on a surface of a heat transfer structure;

FIG. 11B is a schematic diagram of a result of performing a solder pot test in a state where a primer layer is provided on a surface of a heat transfer structure;

FIG. 12A is a schematic diagram of a result of performing a reflow test in a state where an insulation unit directly contacts a heat transfer structure;

FIG. 12B is a schematic diagram of a result of performing a solder pot test in a state where an insulation unit directly contacts a heat transfer structure; and

FIG. 13 is a diagram for explaining a process of processing a core unit according to an embodiment.

### DESCRIPTION OF THE PREFERRED EMBODIMENTS

Various advantages and features of the present disclosure and technologies accomplishing thereof will become apparent from the following description of exemplary embodiments described with reference to the accompanying drawings. However, the present disclosure may be modified in many different forms and it should not be limited to the embodiments set forth herein. These embodiments may be provided so that this disclosure will be thorough and complete, and will fully convey the scope of the disclosure to those skilled in the art. Throughout the specification, like elements refer to like reference numerals.

Terms used in the present specification are for explaining the embodiments rather than limiting the present disclosure. Unless explicitly described to the contrary, a singular form includes a plural form in the present specification. The word “comprise” and/or “comprising” as used herein will be understood to imply the inclusion of stated constituents, steps, operations and/or elements but not the exclusion of any other constituents, steps, operations and/or elements.

For brevity and clarity of the illustration, the drawings illustrate the general structure, and in order to avoid an unnecessarily unclear discussion of the described embodiments of the disclosure, well-known features and detailed description of the technology may be omitted. Additionally, components of the drawings are not necessarily illustrated according to scale. For example, the size of some components of the drawings may be exaggerated compared to the other elements to aid the understanding of the embodiments of the disclosure. The same reference numerals in different drawings represent the same components, and like reference numerals may, but not necessarily, represent similar elements.

The terms such as “first”, “second”, “third” and “fourth” in the spec ti cation and the claims are, if any, used to distinguish between similar components, and, but not necessarily, used to describe particular sequence or chronological order. The terms used as such may be understood to be compatible under an appropriate environment in such a manner that embodiments of the disclosure described herein for example, may operate in a sequence other than as illustrated or explained herein. Similarly, in a case where a method herein is described to include a series of steps, the order of such steps presented herein is not necessarily an order of which steps may be performed, and an arbitrary described step may be omitted and/or an arbitrary other step that is not described herein may be added to the method.

The terms such as “left”, “right”, “front”, “back”, “top”, “bottom”, “upper”, and “down” in the specification and the claims are, if any, used for description and are not necessarily for describing unchangeable relative positions. The terms used as such may be understood to be compatible under an appropriate environment in such a manner that embodiments of the disclosure described herein, for example, may operate in a direction other than as illustrated or explained herein. The term “connected.” used herein is defined as being directly or indirectly connected in an electrical or non-electrical manner. Objects described to be “adjacent” to each other herein may be in physical contact with each other, or close to each other, or in an identical general range or region properly on the context in which the phrase is used.

The construction and effect of the present disclosure will be described in more detail with reference to the accompanying drawings below.

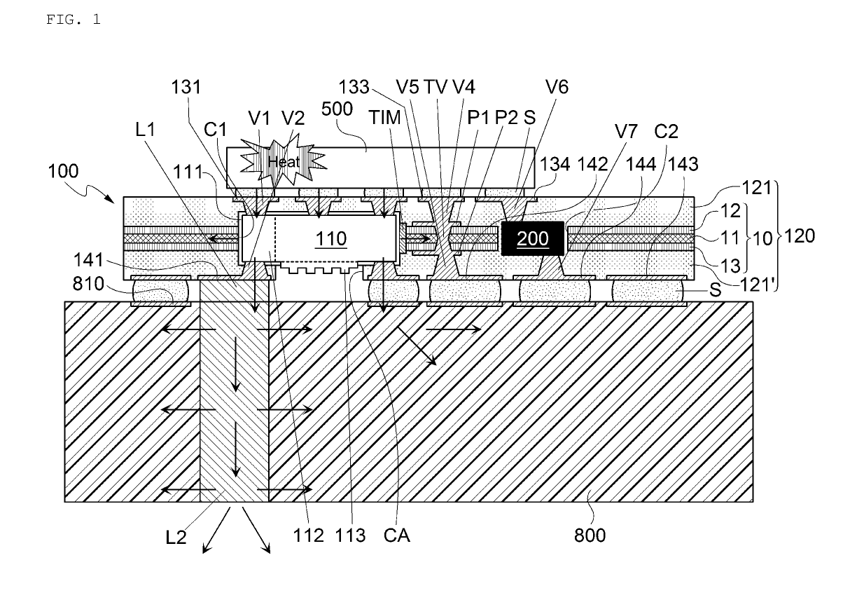

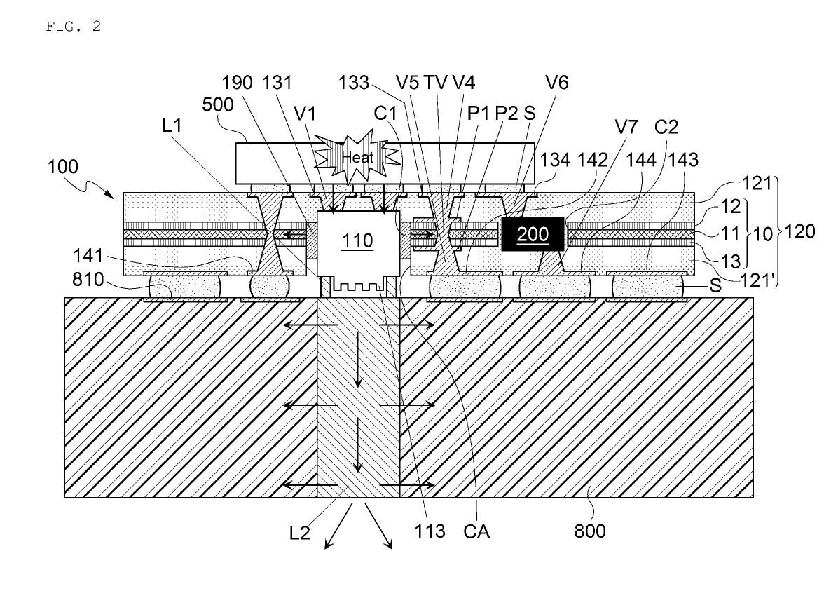

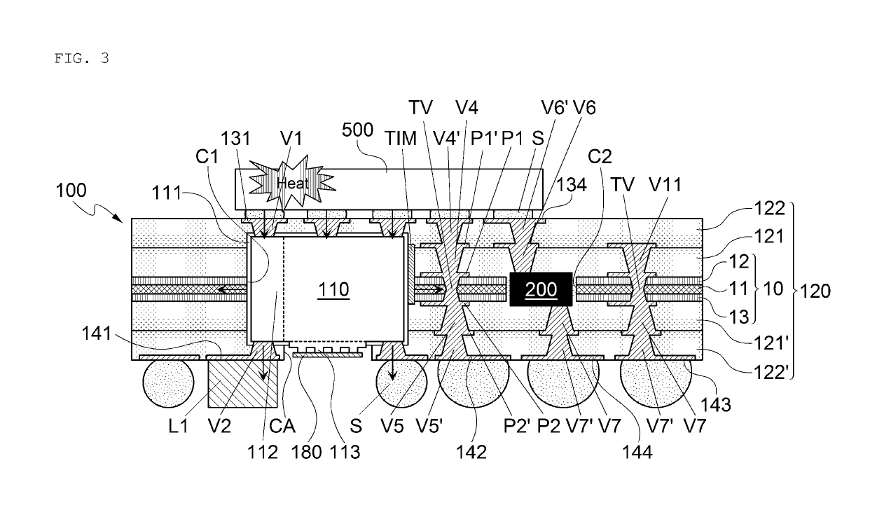

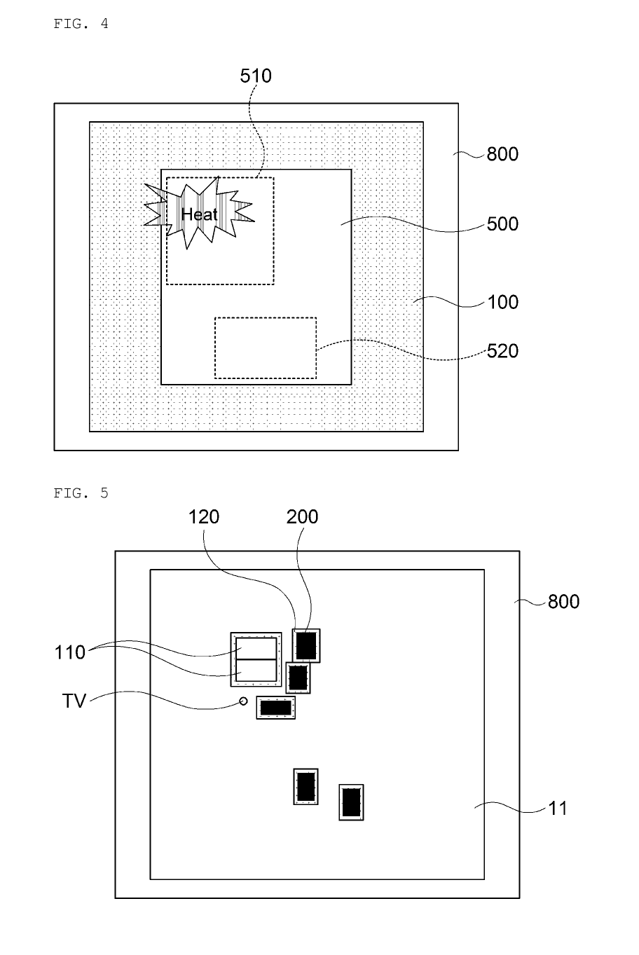

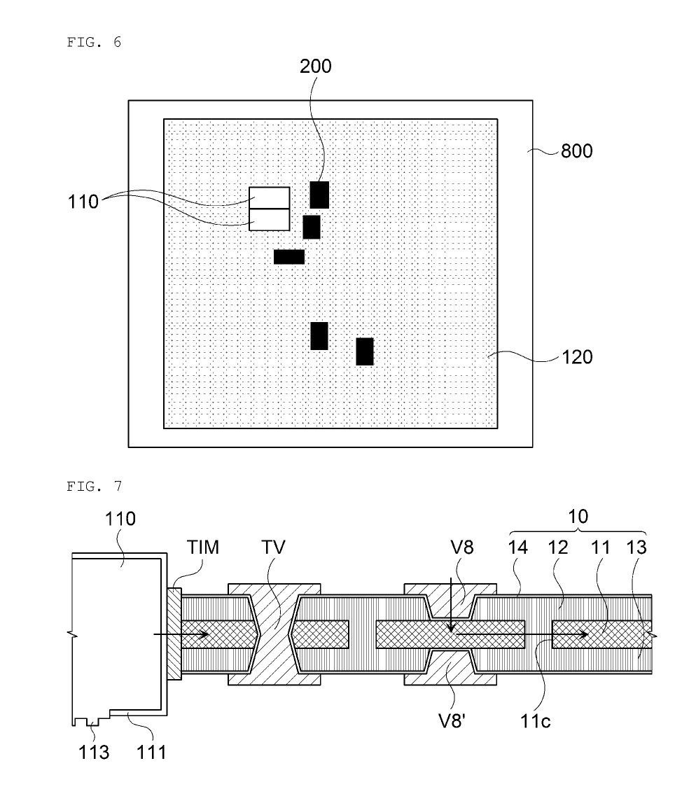

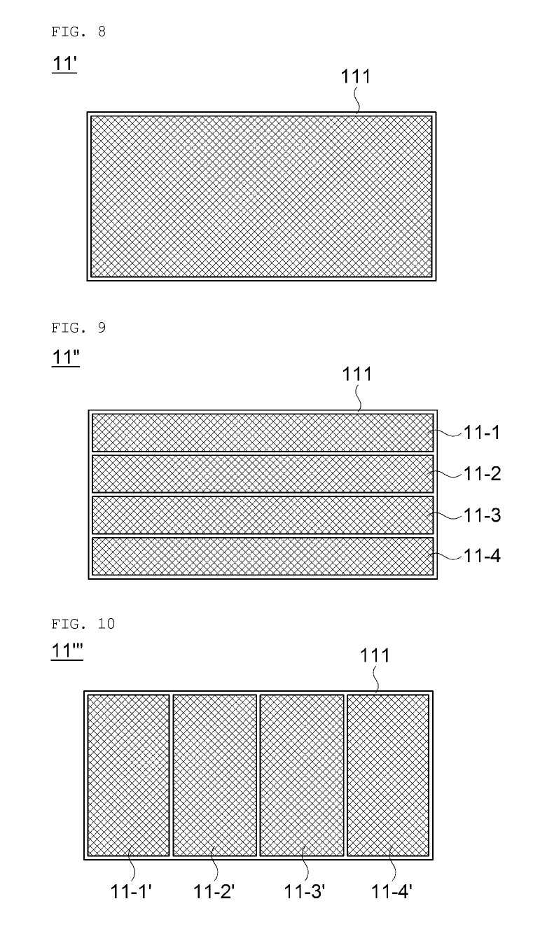

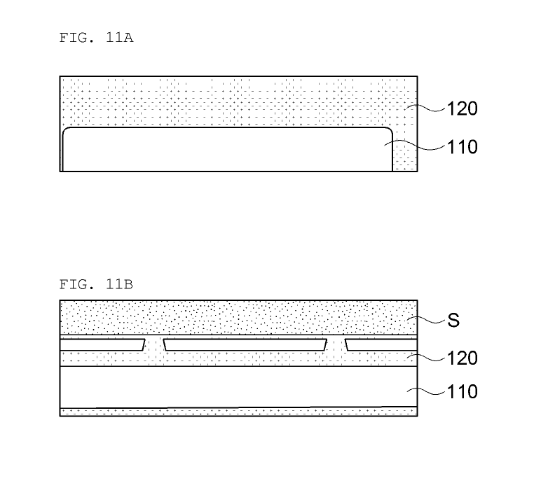

FIG. 1 is a schematic cross-sectional view of a circuit board according to an embodiment. FIG. 2 is a schematic cross-sectional view of a circuit board according to another embodiment. FIG. 3 is a schematic cross-sectional view of a circuit board according to another embodiment. FIG. 4 is a schematic plan view of a circuit board according to an embodiment. FIG. 5 is a schematic horizontal cross-sectional view of a circuit board according to an embodiment. FIG. 6 is a schematic horizontal cross-sectional view of a circuit board according to another embodiment. FIG. 7 is a schematic partial cross-sectional view of a main part of a circuit board according to an embodiment. FIG. 8 is a diagram for explaining a second heat transfer structure according to an embodiment. FIG. 9 is a diagram for explaining a second heat transfer structure according to another embodiment. FIG. 10 is a diagram for explaining a second heat transfer structure according to another embodiment.

The circuit board 100 according to an embodiment includes a first heat transfer structure 110. At least a part of the first heat transfer structure 110 is inserted into an insulation unit 120, and at least another part thereof is exposed to the outside of the insulation unit 120. To this end, an opening unit CA is provided in the insulation unit 120. Such an exposed part of the first heat transfer structure 110 is in contact with air of the outside of the insulation unit 120, and thus heat of the first heat transfer structure 110 may be dissipated through air cooling. In this regard, as shown in FIG. 1, a lower surface of the first heat transfer structure 110 may be exposed to the outside of the insulation unit 120 through the opening unit CA, and the part exposed to the outside of the insulation unit 120 may be referred to as an air cooling unit 113.

The lower surface of the first heat transfer structure 110 may not be wholly exposed to the outside of the insulation unit 120 but may be partially positioned inside the insulation unit 120. As shown in FIG. 1, a part inserted into the inside of the insulation unit 120 may be referred to as a wing unit 112. A via V2 may be in contact with at least a lower surface of the wing unit 112. The air cooling unit 113 may form a corrugated shape or an uneven shape, and thus a surface area of the air cooling unit 113 increases, thereby improving a cooling effect owing to air.

Meanwhile, the first heat transfer structure 110 is formed of a highly thermal conductive material. The first heat transfer structure 110 is formed as a lump shape. In an embodiment, the first heat transfer structure 110 may be formed as a cylindrical or polygonal column shape. The first heat transfer structure 110 may be formed of a metal material such as copper. In another embodiment, the first heat transfer structure 110 may be formed of a non-metal material having a high thermal conductivity such as graphite, graphene, etc.

In an embodiment, the insulation unit 120 may be formed as a single insulation layer or a plurality of insulation layers. In this regard, the insulation unit 120 is formed as three insulation layers 10, 121, and 121′, and an insulation layer positioned in a center part thereof is a core unit 10 in FIG. 1 but are not limited thereto.

In an embodiment, the first heat transfer structure 110 is positioned in the center of the insulation unit 120. When the core unit 10 is provided as shown, a cavity C1 passing through the core unit 10 may be formed so that the first heat transfer structure 110 may be inserted into the cavity C1. Meanwhile, the first lower insulation layer 121′ may cover the above-described wing unit 112 to expose the above-described air cooling unit 113. In this regard, the opening unit CA for exposing the air cooling unit 113 to the outside of the insulation unit 120 is formed in the first lower insulation layer 121′.

Referring to FIG. 2, the first heat transfer structure 110 according to another embodiment is positioned in a recess unit C1+CA provided in the insulation unit 120 so that at least one surface of the first heat transfer structure 110 is exposed to the outside of the insulation unit 120. In this regard, a fixing member 190 may be provided between the first heat transfer structure 110 and the recess unit C1+CA so that the first heat transfer structure 110 may be stably fixed. Meanwhile, the fixing member 190 is implemented as material having a highly thermal conductivity, thereby allowing heat accommodated in the first heat transfer structure 110 to be promptly dispersed to another region of the circuit board 100. The first heat transfer structure 110 according to the present embodiment may also include the air cooling unit 113 similarly to the embodiment described with reference to FIG. 1. In this regard, a third heat transfer structure L1 is provided in at least a part of the lower surface of the first heat transfer structure 110, thereby increasing a heat transfer rate between an additional board 800 and the first heat transfer structure 110. Accordingly, the heat of the first heat transfer structure 110 may be dispersed into the air through the air cooling unit 113 and simultaneously the additional board 800 may be promptly moved through the third heat transfer structure L1.

Meanwhile, the above-described recess unit C1+CA may be formed by using various methods. For example, a first upper insulation layer 121 is formed in a state where the first heat transfer structure 110 is inserted into the core unit 10 in which the cavity C1 is provided. Thereafter, the first heat transfer structure 110 is fixed by filling a fixing member 190 between the first heat transfer structure 110 and the cavity C1. Thereafter, the recess unit C1+CA may be implemented in a way to remove a part of the first lower insulation layer 121′ such that at least the lower surface of the first heat transfer structure 110 may be exposed after forming the first lower insulation layer 121′. In a state where the recess unit C1+CA is formed in the insulation unit 120, a method of filling the fixing member 190 after inserting the first heat transfer structure 110 may be applied.

Meanwhile, referring to FIG. 3, an air cooling auxiliary layer 180 may be combined to the air cooling unit 113 of the first heat transfer structure 110. In this regard, the air cooling auxiliary layer 180 performs a function of more promptly dispersing heat of the air cooling unit 113 into the air, may be formed of a material of graphite or graphene, and may be formed as a sheet shape to be combined to the air cooling unit 113. In this regard, the air cooling auxiliary layer 180 is combined to the air cooling unit 113 in such a manner that the air cooling auxiliary layer 180 is directly in contact with lowest points of the air cooling unit 113 and is not in contact with other surfaces thereof. Accordingly, the heat of the first heat transfer structure 110 is moved to the air cooling auxiliary layer 180 through a contact point of the air cooling unit 113 and the air cooling auxiliary layer 180 and spreads into the air on the surface of the air cooling auxiliary layer 180. At same time, air flows into an empty space between the air cooling auxiliary layer 180 and the air cooling unit 113 so that the heat of the first heat transfer structure 110 may be dissipated through air cooling. Meanwhile, the air cooling auxiliary layer 180 is shown in FIG. 3 but may be applied to the embodiment described with reference to FIG. 1 or 2.

Referring to FIG. 1 again, in an embodiment, a via formed in the insulation unit 120 may be in contact with the first heat transfer structure 110. Hereinafter, a via positioned in an upper portion of the first heat transfer structure 110 is referred to as a first via V1, and a via positioned in a lower portion of the first heat transfer structure 110 is referred to as a second via V2. In this regard, at least one metal pattern may be provided in the insulation unit 120. Hereinafter, a metal pattern contacting the first via V1 is referred to as a first metal pattern 131, and a metal pattern contacting the second via V2 is referred to as a second metal pattern 141. A fourth via V4 and a fifth via V5 may be provided in the insulation unit 120. A metal pattern contacting one end of the fourth via V4 is referred to as a third metal pattern 133. A metal pattern contacting another end of the fifth via V5 is referred to as a fourth metal pattern 142.

In an embodiment, the first heat transfer structure 110 may perform a function of keeping heat. As the volume of the first heat transfer structure 110 becomes great, the function increases. Thus, the first heat transfer structure 110 may be formed as a column shape as shown. If areas of lower surfaces are identical according to the column shape, the volume of the first heat transfer structure 110 may be maximized. If lower and upper shapes of the first heat transfer structure 110 form polygonal, in particular, rectangular shapes, this may meet a miniaturization trend of a first electronic component 500, miniaturization of the circuit board 100, a fine pattern pitch, etc. compared to a case where the lower and upper shapes of the first heat transfer structure 110 are circular or oval shapes. As shown, the volume of the first heat transfer structure 110 is remarkably larger than that of a general via such as the first via V1 through a seventh via V7. Thus, a via may be in plural contacts with the surface of the first heat transfer structure 110, in particular, the upper surface or the lower surface. That is, an area itself of the upper surface and the lower surface of the first heat transfer structure 110 is greater than that of usual vias and an entire volume thereof is greater two times than that of the usual vias. Accordingly, the heat may be promptly absorbed from a heat source, and may be dispersed to another path connected to the first heat transfer structure 110. A part of the heat of the first heat transfer structure 110 may be dissipated into the air through the air cooling unit 113. If a thickness of the first heat transfer structure 110 is increased, a distance between the first heat transfer structure 110 and a hot spot is reduced, and thus a time taken to move heat of the hot spot to the first heat transfer structure 110 may be further reduced.

In an embodiment, a first electronic component 500 may be mounted in one side of the circuit board 100. The circuit board 100 may be mounted in one side of the additional board 800 such as a main board. In this regard, the first electronic component 500 may be a component of an application processor (AP) and may generate heat when operating.

Meanwhile, the heat is generated when the first electronic component 500 operates. If the generated heat is sensed, since heating is relatively intense, a region in which a high temperature is measured exists. Such a region is referred to as a hot spot. The hot spot may be formed in a predetermined region of the circuit board 100, and, in particular, is formed around the whole or a part of the first electronic component 500. The hot spot is formed around a power terminal of the first electronic component 500 or in a region in which a switching device is relatively condensed.

On the other hand, the first electronic component 500 may include a region having a relatively high performance specification and a region having a relatively low performance specification. For example, a processor to which cores having a clock speed of 1.8 GHz are connected and a processor to which cores having a clock speed of 1.2 GHz are connected may be provided in different regions of the first electronic component 500. Referring to FIG. 3, in an embodiment, the first electronic component 500 may include a first unit region 510 and a second unit region 520. In this regard, the first unit region 510 performs an operation process at a faster speed than the second unit region 520, and thus the first unit region 510 may consume more power than the second unit region 520, and may generate more heat than the second unit region 520.

In the circuit board 100 according to an embodiment, the first heat transfer structure 110 is positioned in a region adjacent to the host spot. Accordingly, the circuit board 100 may promptly receive the heat generated in the hot spot and may disperse the heat to another region of the circuit board 100 or another device such as a main board to which the circuit board 100 is combined, etc.

In an embodiment, at least a part of the first heat transfer structure 110 is positioned in a vertical downward region of the first electronic component 500.

Meanwhile, a second electronic component 200 may be further provided in the circuit board 100 according to an embodiment. In this regard, a device such as a capacitor, an inductor, a resistor, etc. may correspond to the second electronic component 200.

When the first electronic component 500 is an application processor, the capacitor, etc. may be connected to the application processor to reduce power noise. In this regard, the shorter the path between the capacitor and the application processor, the more the reduction effect of the power noise increases.

Thus, at least a part of the second electronic component 200 may be positioned in the vertical downward region of the first electronic component 500, thereby increasing the reduction effect of the power noise.

In an embodiment, a most part of the first heat transfer structure 110 may be positioned in the vertical downward region of the first electronic component 500. An area of a top surface of the first heat transfer structure 110 may be smaller than that of a top surface of the first electronic component 500. Furthermore, the area of a top surface of the first heat transfer structure 110 may be determined to correspond to a width of the hot spot region of the first electronic component 500.

Accordingly, the heat of the hot spot may be promptly moved to the first heat transfer structure 110. It is advantageous to the lightweight of the circuit board 100 and reduction of a warpage. In addition, efficiency of a process of placing the first heat transfer structure 110 in the circuit board 100 may be improved.

Meanwhile, a most part of the second electronic component 200 may be positioned in the vertical downward region of the first electronic component 500. In this regard, the second electronic component 200 may be positioned in the vertical downward region of the first electronic component 500 in which the above-described first heat transfer structure 110 is not positioned. The first heat transfer structure 110 may be positioned in a region closer to the hot spot compared to the second electronic component 200.

Referring to FIGS. 1 through 5, it may be understood that the first heat transfer structures 110 and the second electronic components 200 may be inserted into cavities included in the first core layer 11. That is, the first cavity C1 and a second cavity C2 may be provided in the core unit 10, the first heat transfer structure 110 may be inserted into the first cavity C1, and the second electronic component 200 may be inserted into the second cavity C2. The first heat transfer structures 110 and the second electronic components 200 may be disposed to be adjacent to each other in the vertical downward region of the first electronic component 500. In particular, it may be understood that the first heat transfer structures 110 may be intensively disposed around the hot spot of FIG. 4.

Accordingly, the heat of the hot spot may be promptly moved while maximizing the effect of reducing power noise due to the second electronic component 200.

In an embodiment, the first electronic component 500 may be combined to the circuit board 100 via a solder S, etc. In this regard, the first electronic component 500 may be combined to the first metal pattern 131, the third metal pattern 133, the seventh metal pattern 134, etc. described above via the solder S.

The second metal pattern 141, the fourth metal pattern 142, a fifth metal pattern 143, a sixth metal pattern 144, etc. of the circuit board 100 may be connected to the additional board 800 such as the main board via the solder S, etc. In an embodiment, a third heat transfer structure L1 formed of a material and a shape similar to those of the first heat transfer structure 110 may be provided between the second metal pattern 141 and the additional board 800, other than the general solder S. That is, to promptly transfer the heat of the first heat transfer structure 110 to the additional board 800, the second metal pattern 141 and the additional board 800 may be connected to each other by using the third heat transfer structure L1 forming a lump shape using a material having a higher thermal conductivity than that of the general solder S. A heat radiation unit L2 may be provided in the additional board 800 so that the heat of the third heat transfer structure L1 may be promptly received and dispersed or radiated. The heat radiation unit L2 may be exposed in a direction of a top surface of the additional board 800, and, if necessary, may be exposed to a direction of a bottom surface thereof, thereby improving heat radiation efficiency.

Accordingly, the heat generated in the hot spot may be promptly transferred to the additional board 800 through a path of the first metal pattern 131, the first via V1, the first heat transfer structure 110, the second via V2, and the second metal pattern 141.

Meanwhile, when the first metal pattern 131 through the seventh metal pattern 134 are provided to be exposed to an external surface of the insulation unit 120 as shown in FIG. 1, the first through fourth metal patterns 142 may perform a function as a connection pad. Although not shown, a solder resist layer may be provided to expose a part of a metal pattern while protecting other parts of the metal pattern and the insulation unit 120, etc. Various surface treatment layers such as a nickel-gold plating layer may be provided on surfaces of metal patterns exposed to the outside of the solder resist layer.

On the other hand, when a terminal connected to the first metal pattern 131 among terminals of the first electronic component 500 is a terminal for transmitting and receiving a signal, a path including the first via V1, the first heat transfer structure 110, the second via V2, and the second metal pattern 141 may perform a function of transmitting the signal. In this regard, the connection pad of the additional board 800 connected to the second metal pattern 141 or terminals may also perform the function of transmitting the signal.

Meanwhile, when the terminal connected to the first metal pattern 131 among the terminals of the first electronic component 500 is not the terminal for transmitting and receiving the signal, the path including the first via V1, the first heat transfer structure 110, the second via V2, and the second metal pattern 141 may be electrically connected to a separate ground terminal that is not shown. In this regard, the connection pad of the additional board 800 connected to the second metal pattern 141 or the terminals may also be electrically connected to the separate ground terminal that is not shown. In this regard, the ground terminal may be provided in at least one of the circuit board 100 or the additional board 800.

When the terminal connected to the first metal pattern 131 among the terminals of the first electronic component 500 is the power terminal, the path including the first via V1, the first heat transfer structure 110, the second via V2, and the second metal pattern 141 may be electrically connected to a separate power providing circuit that is not shown. In this regard, the connection pad of the additional board 800 connected to the second metal pattern 141 or the terminals may also be electrically connected to the separate power providing circuit that is not shown. In this regard, the power providing circuit may be provided in at least one of the circuit board 100 or the additional board 800.

The terminal connected to the first metal pattern 131 among the terminals of the first electronic component 500 may be a dummy terminal. In this regard, the dummy terminal may perform a function only as a path to transfer the heat of the first electronic component 500 to the outside of the first electronic component 500.

Referring to FIGS. 1 through 10, the circuit board 100 according to an embodiment may include the core unit 10. The core unit 10 may function to relieve a problem due to the warpage by reinforcing rigidity of the circuit board 100. Heat generated from a local region such as the hot spot described above may be promptly dispersed to another part of the circuit board 100 by including a highly thermal conductive material in the core unit 10, thereby relieving a problem due to overheat.

Meanwhile, the first upper insulation layer 121 may be provided on a top surface of the core unit 10, and the first lower insulation layer 121′ may be provided on a bottom surface of the core unit 10. A second upper insulation layer 122 and a second lower insulation layer 122′ may be further provided as necessary.

In an embodiment, a second heat transfer structure may be included in the core unit 10. For example, the core unit 10 may include the first core layer 11 formed of graphite or graphene. In this regard, graphite has a remarkably highly thermal conductivity in a direction of an XY plane, thereby effectively and promptly dispersing the heat.

In an embodiment, the second heat transfer structure may be directly in contact with a side surface of the first heat transfer structure 110. For example, the side surface of the second heat transfer structure may be exposed to the first cavity C1 included in the core unit 10, and the first heat transfer structure 110 may be in contact with the first cavity C1. In another embodiment, the highly thermal conductive material may be provided in a region between the second heat transfer structure and the first heat transfer structure 110. In this regard, a thermal interface material (TIM) may be applied as the highly thermal conductive material. The TIM may include a polymer-metal complex material, a ceramic complex material, and a carbon based complex material, etc. For example, a material (having a thermal conductivity of about 660 W/mk) in which epoxy and a carbon fiber filler are mixed, silicon nitride (Si3N4, having a thermal conductivity of about 200-320 W/mk), epoxy, and boron nitride (BN, having a thermal conductivity of about 19 W/mk) may be applied as the TIM. Accordingly, the heat flowing through the first heat transfer structure 110 may be moved in a vertical direction and may be promptly dispersed in a horizontal direction through the second heat transfer structure.

As such, since the first heat transfer structure 110 and the second heat transfer structure are directly in contact with each other or are connected to each other via the TIM, the heat may be more promptly dispersed compared to a case where the heat of the first electronic component 500 is promptly moved to the first heat transfer structure 110 and then transferred downward. Compared to a case where a temperature is excessively increased in a specific region such as the hot spot, etc. in view of the circuit board 100, since the heat is uniformly dispersed throughout the circuit board 100, a temperature deviation of each component mounted in the circuit board 100 or each element may be relieved, thereby improving reliability. Since the heat is promptly dispersed throughout the circuit board 100, the circuit board 100 functions as a heat dissipation plate as a whole, thereby implementing an effect of increasing a heat dissipation area.

In an embodiment, a first circuit pattern P1 and a second circuit pattern P2 may be provided on the surface of the core unit 10, and may be electrically connected to each other by a through-via (TV) passing through a core. The first circuit pattern P1 may be connected to the third metal pattern 133 via the fourth via V4. The second circuit pattern P2 may be connected to the fourth metal pattern 142 via the fifth via V5. The third metal pattern 133 may be connected to the first electronic component 500 via the solder S. The fourth metal pattern 142 may be connected to the connection pad 810 of the additional board 800 via the solder S. Accordingly, an electrical signal may be transmitted and received between the first electronic component 500 and the additional board 800.

Meanwhile, a second core layer 12 may be provided on one surface of the first core layer 11, and a third core layer 13 may be provided on another surface of the first core layer 11. In an embodiment, at least one of the second core layer 12 and the third core layer 13 may be formed of an insulation material such as PPG, etc. In another embodiment, the second core layer 12 and the third core layer 13 may be formed of metal such as copper or invar. In another embodiment, the first core layer 11 may be formed of invar, and the second core layer 12 and the third core layer 13 may be formed of copper. In this regard, when at least one of the second core layer 12 and the third core layer 13 is formed of a conductive material, since the first circuit pattern P1 or the second circuit pattern P2 is provided on the surface of the core unit 10, a problem may occur that a signal is transmitted to an unintended path, and thus means for securing insulation may be provided on the surface of the core unit 10.

In an embodiment, the second electronic component 200 is inserted into the second cavity C2 of the core unit 10. The second electronic component 200 may be connected to the seventh metal pattern 134 via the sixth via V6, and may be connected to the sixth metal pattern 144 via the seventh via V7. Meanwhile, the second electronic component 200 may be a passive device such as an inductor, a capacitor, etc. An active device such as an IC may be mounted as the second electronic component 200 as necessary. In particular, when the second electronic component 200 is the capacitor, a terminal of the first electronic component 500 connected to the seventh metal pattern 134 may be a power terminal. That is, the second electronic component 200 may be mounted as a decoupling capacitor to perform a function of reducing power noise of the first electronic component 500.

In this case, the shorter the path between the second electronic component 200 and the first electronic component 500, the greater the noise reduction effect increases. To this end, in the circuit board 100 according to an embodiment, at least a part of the second electronic component 200 is disposed in the vertical downward region of the first electronic component 500.

Although not shown, a recess unit in which a part of the core unit 10 is sunken may be provided instead of the cavity passing through the core unit 10. The first heat transfer structure 110 or the second electronic component 200 may be inserted into the recess unit.

Meanwhile, referring to FIG. 1, a thickness of the first heat transfer structure 110 may be implemented to be greater than a thickness from a bottom surface of the second circuit pattern P2 to a top surface of the first circuit pattern P1. Furthermore, the top surface of the first heat transfer structure 110 may be positioned closer to the top surface of the circuit board 100 than the top surface of the first circuit pattern P1. Accordingly, a function of keeping heat by increasing a heat capacity of the first heat transfer structure 110 may be improved. A distance between the first heat transfer structure 110 and the hot spot is reduced, and thus a time taken to move the heat of the hot spot to the first heat transfer structure 110 may be further reduced.

Referring to FIG. 3, the second upper insulation layer 122 may be formed on the first upper insulation layer 121. In this case, it may be understood that a height of the first via V1 or the second via V2 provided between an external surface of the circuit board 100 and the first heat transfer structure 110 may be smaller than that of a via connecting the external surface of the circuit board 100 and inner layer patterns P1′ and P2′ in such a manner that the heat capacity of the first heat transfer structure 110 may be increased and simultaneously a heat dispersion speed may be improved.

Referring to FIG. 7, an insulation film 14 may be provided on the surface of the core unit 10. In an embodiment, the first core layer 11 through the third core layer 13 may have a thermal conductivity and an electric conductivity as well. Thus, when the first circuit pattern P1 is provided on the surface of the core unit 10, it is necessary for preventing a phenomenon of conducting electricity to the unintended path by the core unit 10. In this regard, the insulation film 14 may be formed by vapor depositing parylene on the surface of the core unit 10. That is, in a state where a through-via hole for forming the through-via (TV) shown in FIG. 7 is processed in the core unit 10, an insulation material is provided on the surface of the core unit 10, thereby forming the insulation film 14 in the through-via (TV) hole. Accordingly, insulation between the through-via (TV) or the first circuit pattern P1, the second circuit pattern P2, etc. and the core unit 10 may be secured.

Meanwhile, in an embodiment, a core via hole that passes though the second core layer 12 and the third core layer 13 and exposes a part of the first core layer 11 may be formed. An eighth via formed by providing a conductive material in the core via hole may be directly in contact with the first core layer 11. In this regard, when the insulation film 14 is formed on the surface of the core unit 10 in the state where the core via hole is provided, since the insulation film 14 is formed on the surface of the exposed first core layer 11, the first core layer 11 and the eighth via V8 may be in contact with each other with the insulation film 14 disposed therebetween. When the heat is moved to the eighth via V8 that is directly (or indirectly when there is the insulation film 14) in contact with the first core layer 11, the heat may be promptly dispersed in a direction horizontal to the circuit board 100 along the first core layer 11.

In an embodiment, the second heat transfer structure is formed of graphite or graphene. In this case, graphite or graphene has a relatively low interlayer coherence. Thus, the second heat transfer structure may be damaged during a process of manufacturing the circuit board 100 or the interlayer coherence may be weakened after the circuit board 100 is completed, which may cause a problem of reliability.

As shown in FIG. 7, a through hole 11c may be provided in the first core layer 11, and the first core layer 11 may be firmly supported by integrally connecting the second core layer 12 and the third core layer 13 via the through hole 11c. Accordingly, although the first core layer 11 is formed of graphite, the interlayer coherence may be reinforced.

Meanwhile, referring to FIG. 8, an example in which a primer layer 111 is provided in an external surface of the first core layer 11 is illustrated. That is, the primer layer 111 is provided on an external surface of a graphite sheet, thereby improving the interlayer coherence. In this regard, the primer layer 111 may improve the interlayer coherence between graphite and may perform a function of improving the interlayer coherence between the first core layer 11 and the second core layer 12 and between the first core layer 11 and the third core layer 13.

In another embodiment, referring to FIG. 8, the first core layer 11 may be implemented by stacking monomers 11-1, 11-2, 11-3, and 11-4 formed by providing the primer layer 111 on the surface of graphite in a vertical direction. In this case, a delamination problem of the first core layer 11 in the vertical direction may be relieved while minimizing a reduction of a horizontal heat dissipation function of the first core layer 11.

In another embodiment, referring to FIG. 9, the first core layer 11 may be implemented by combining monomers 11-1′, 11-2′, 11-3′, and 11-4′ formed by providing the primer layer 111 on the surface of graphite in a horizontal direction. In this regard, the XY plane of graphite may be disposed parallel to the vertical direction. In this case, a heat dissipation function in the horizontal direction may be slightly reduced, whereas a vertical heat dissipation function using the first core layer 11 may be improved.

Meanwhile, the first heat transfer structure 110 included in the circuit board 100 according to an embodiment includes an adhesion improving unit for improving an adhesion with the insulation unit 120.

When the surface of the first heat transfer structure 110 is directly in contact with the insulation unit 120, a phenomenon in which the first heat transfer structure 110 and the insulation unit 120 have a gap therebetween may occur during a reflow process or a solder pot process, which is referred to as a delamination phenomenon. In this regard, as means for improving the adhesion with the insulation unit 120, the primer layer 111 provided on the surface of the first heat transfer structure 110 may be included. In an embodiment, the primer layer 111 may be formed of primer including iso propyl alcohol (IPA) or acrylil based silan. The primer layer 111 may be formed of 3-(trimethoxysilyl)propylmethacrylate (MPS), and may have a silan based additive.

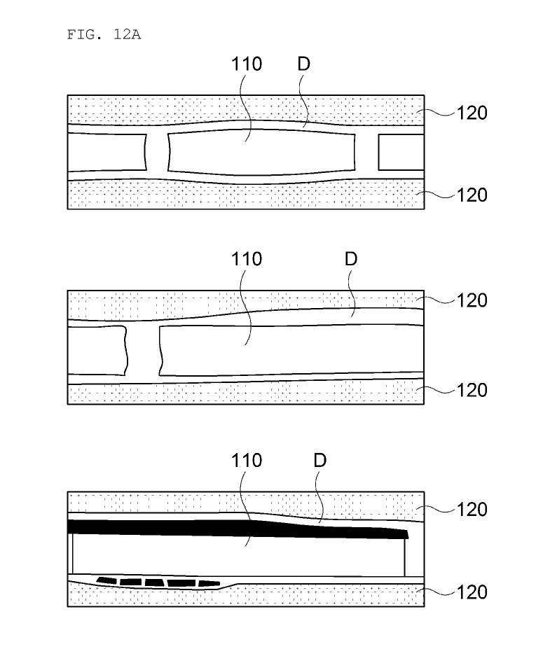

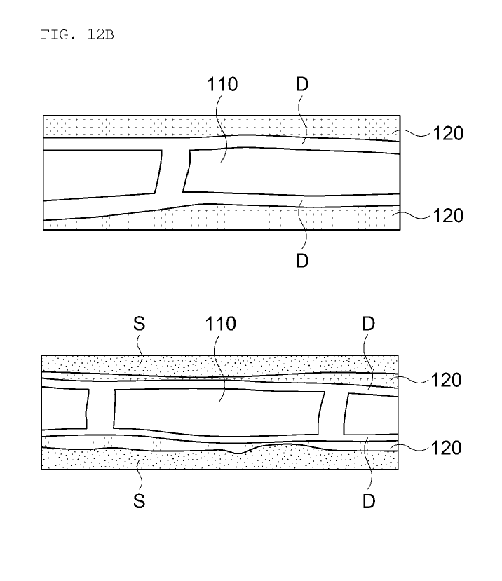

FIG. 11A is a schematic diagram of a result of performing a reflow test in a state where the primer layer 111 is provided on a surface of a heat transfer structure. FIG. 11B is a schematic diagram of a result of performing a solder pot test in a state where the primer layer 111 is provided on a surface of a heat transfer structure. FIG. 12A is a schematic diagram of a result of performing a reflow test in a state where the insulation unit 120 directly contacts a heat transfer structure. FIG. 12B is a schematic diagram of a result of performing a solder pot test in a state where the insulation unit 120 directly contacts a heat transfer structure.

Referring to FIGS. 11A through 12B, it may be understood that when the primer layer 111 is not present, if the reflow process or the solder pot process is performed, although a gap space D between the heat transfer structure and the insulation unit 120 is formed, when a primer is provided on a surface of the heat transfer structure, an adhesion between the heat transfer structure and the insulation unit 120 may be improved. In this regard, the heat transfer structure may mean at least one of the first heat transfer structure 110 or the second heat transfer structure.

Meanwhile, the adhesion between the first heat transfer structure 110 and the insulation unit 120 may be improved by performing surface treatment such as blackening treatment and surface roughing treatment on a surface of the first heat transfer structure 110.

However, if the surface treatment described above is performed on the surface of the first heat transfer structure 110, a problem may occur in a manufacturing process. For example, a color of the first heat transfer structure 110 may be different due to the surface treatment. In this case, an error may frequently arise during a process in which automatic equipment that mounts the first heat transfer structure 110 on a predetermined location on the insulation unit 120 recognizes the first heat transfer structure 110.

Accordingly, a delamination phenomenon between the first heat transfer structure 110 and the insulation unit 120 may be reduced in the circuit board 100 according to an embodiment.

Meanwhile, referring to FIG. 1, etc. again, when the primer layer 111 is provided on the surface of the first heat transfer structure 110, the first via V1 or the second via V2 may also pass through the primer layer 111 to be directly in contact with the first heat transfer structure 110. Accordingly, a reduction in the heat transfer performance due to the primer layer 111 may be minimized.

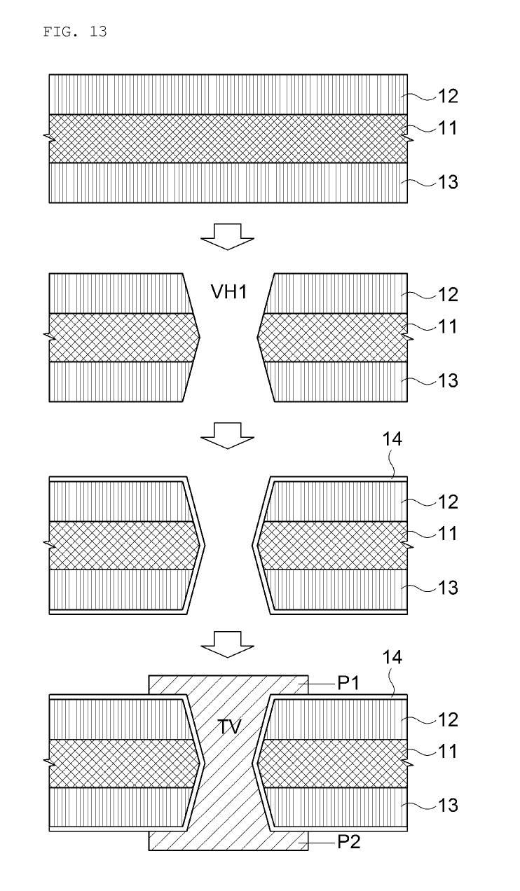

FIG. 13 is a diagram for explaining a process of processing the core unit 10 according to an embodiment.

Referring to FIG. 13, a via hole VH1 may be formed in a core including the first core layer 11, the second core layer 12, and the third core layer 13, the insulation film 14 is formed on a surface of the core by including an inner surface of the via hole VH1, and then the first circuit pattern P1, the through-via (TV), and the second circuit pattern P2 may be formed. Accordingly, insulation between the first circuit pattern P1, etc. and the core unit 10 may be secured.

As set forth above, according to an exemplary embodiment of the present disclosure, a heat dissipation performance of a circuit board is improved in addition to a lightweight, thin, short, and small circuit board.

The heat dissipation performance may be improved while securing the reliability of the circuit board, thereby effectively solving a heating problem due to a high-functional electronic product.

A problem due to heating of a local region such as a hot spot may be solved while reducing power noise in an embodiment.

The detailed description described above is only to illustrate the present disclosure. Although the exemplary embodiments of the present disclosure have been described, the present disclosure may be also used in various other combinations, modifications, and environments. In other words, the present disclosure may be changed or modified within the range of concept of the disclosure disclosed in the specification, the range equivalent to the disclosure and/or the range of the technology or knowledge in the field to which the present disclosure pertains. The exemplary embodiments described above have been provided to explain the best state in carrying out the present disclosure. Therefore, they may be carried out in other states known to the field to which the present disclosure pertains in using other disclosures such as the present disclosure and also be modified in various forms required in specific application fields and usages of the disclosure. Therefore, it is to be understood that the disclosure is not limited to the disclosed embodiments. It is to be understood that other embodiments are also included within the spirit and scope of the appended claims.

What is claimed is:

1. A circuit board comprising a first heat transfer structure formed of a thermal conductive material, wherein at least a part of the first heat transfer structure is inserted into an insulation unit and another part thereof is exposed to outside of the insulation unit.

2. The circuit board according to claim 1, wherein at least a part of an air cooling unit that is a region exposed to the outside of the insulation unit in the first heat transfer structure is formed as a wrinkled or uneven shape.

3. The circuit board according to claim 2, wherein a part of a lower surface of the first heat transfer structure excluding the air cooling unit comes into the inside of the insulation unit to be in contact with the insulation unit.

4. The circuit board according to claim 3, wherein a via is in contact with at least a part of the part of the lower surface of the first heat transfer structure excluding the air cooling unit.

5. The circuit board according to claim 2, further comprising:
a via having one surface in contact with a surface of the first heat transfer structure; and
a metal pattern in contact with another surface of the via.

6. The circuit board according to claim 5, further comprising:
a first electronic component including a first region and a second region whose temperature is higher than that of the first region when the first electronic component operates; and
a coupling member in contact with at least a part of the second region and the metal pattern.

7. The circuit board according to claim 2, further comprising:
an air cooling auxiliary layer in contact with at least a part of lowest points of the air cooling unit and formed of a graphite or graphene material.

8. The circuit board according to claim 1, wherein the insulation unit is provided with a recess unit sunken in one surface of the insulation unit in a direction of another surface of the insulation unit, and
the first heat transfer structure is inserted into the recess unit.

9. The circuit board according to claim 8, wherein at least a part of an air cooling unit that is a region exposed to the outside of the insulation unit in the first heat transfer structure is formed as a wrinkled or uneven shape.

10. The circuit board according to claim 9, wherein an adhesion improving unit for improving an adhesion between the first heat transfer structure and the insulation unit is provided on the surface of the first heat transfer structure.

11. A circuit board mounted in a surface of an electronic component, the circuit board comprising:
a first insulation layer including a cavity into which at least a part of a first heat transfer structure is inserted;
a first via passing through a second insulation layer provided in an upper side of the first insulation layer;
a second via passing through a third insulation layer provided in a lower side of the first insulation layer;
a first metal pattern provided on an external surface of a second insulation layer and in contact with one end of the first via; and
a second metal pattern provided on an external surface of a third insulation layer and in contact with one end of the second via,
wherein at least a part of the first heat transfer structure is exposed to outside of the third insulation layer, and a thermal conductive path is formed between the first heat transfer structure and the electronic component.

12. The circuit board according to claim 11, wherein the first heat transfer structure is formed as a polyhedron including a top surface and a bottom surface,
a part of the bottom surface of the first heat transfer structure is a wing unit inserted into an inner side of an insulation unit,
a remaining part of the bottom surface of the first heat transfer structure is an air cooling unit exposed to the outside of the insulation unit, and
another end of the second via is in contact with the wing unit.

13. The circuit board according to claim 12, wherein a first coupling member is in contact with the first metal pattern, and a first electronic component is in contact with the first coupling member.

14. The circuit board according to claim 13, wherein a second coupling member is in contact with the second metal pattern, an additional board is in contact with the second coupling member, and heat generated from the first electronic component is transferred to the additional board through the first coupling member, the first metal pattern, the first via, the first heat transfer structure, the second via, the second metal pattern, and the second coupling member.

15. The circuit board according to claim 14, wherein the second coupling member is coupled to a top surface of a heat dissipation unit having an upper surface and a lower surface exposed by passing through the additional board and formed of a thermal conductive material.

16. The circuit board according to claim 15, wherein the second coupling member is formed of the thermal conductive material and has a lump shape.

17. The circuit board according to claim 14, wherein the first electronic component includes a first region and a second region having a higher clock speed than the first region, and
a distance from the second region to the first coupling member is shorter than that from the first region to the first coupling member.

18. The circuit board according to claim 17, wherein the second coupling member is coupled to a top surface of a heat dissipation unit having an upper surface and a lower surface exposed by passing through the additional board and formed of a thermal conductive material, is formed of the thermal conductive material, and has a lump shape.

19. The circuit board according to claim 11, wherein a first electronic component is mounted in a top portion of the circuit board, and
at least a part of the first heat transfer structure is positioned in a vertical downward region of the first electronic component.

20. The circuit board according to claim 19, further comprising:
a second electronic component provided in the insulation unit and having at least a part positioned in the vertical downward region of the first electronic component.

21. The circuit board according to claim 20, wherein the first electronic component includes a first region and a second region whose temperature is higher than that of the first region when the first electronic component operates, and
the second region is closer to the first heat transfer structure than the first region.
